(19) United States
(12) Patent Application Publication
(10) Pub. No.: US 2005/0081907 A1
(43) Pub. Date: Apr. 21, 2005

(54) Electro-active device having metal-containing layer

(76) Inventors: Larry Neil Lewis, Scotia, NY (US); Jie Liu, Niskayuna, NY (US); Kevin Henry Janora, Schenectady, NY (US)

Correspondence Address: General Electric Company;CRD Patent Docket Rm 4A59, Bldg. K-1, P.O. Box 8, Schenectady, NY, 12301, US

(21) Appl. No.: 10/689,792

(22) Filed: Oct. 20, 2003

(51) Int. Cl. H01L 29/40; H05B 33/26; H01L 31/0224; B05D 5/12; B05D 3/00

(52) U.S. Cl. 136/243; 428/209; 428/332; 428/917; 313/506; 257/79; 257/183; 427/58; 427/66; 427/74; 257/431

(57) ABSTRACT

An electro-active device, such as a photovoltaic cell or an OLED, is disclosed. The electro-active device comprises a substrate; a first electrode disposed on a surface of the substrate; a second electrode; at least one electro-active layer disposed between the first electrode and the second electrode, wherein the at least one active layer comprises one of a light absorbing layer and a light emitting layer; and a first metal-containing layer disposed between the first electrode and the electro-active layer; and a second metal-containing layer disposed between the least one active layer and one of the first electrode and the second electrode. The first metal-containing layer comprises at least one metal disposed in a plurality of domains. At least one of the first electrode and the second electrode is a transparent electrode. A metal-containing layer for an electro-active device and a method of making such a metal-containing layer are also disclosed.

### BACKGROUND OF INVENTION

The invention relates to an electro-active device, such as a photovoltaic cell or an organic light emitting device (OLED). More particularly, the invention relates to a method of depositing a layer of metal at low temperatures to form a metal-containing layer for such an electro-active device.

Certain materials and devices display electronic characteristics, features and uses. Electro-active devices such as photovoltaic cells and organic light emitting diodes (referred hereinafter to as “OLEDs”) are widely used in information displays, solar cells, fuel cell components, and in specialty electronics. One of the features of such devices is a metal-containing conductive or catalytic layer that connects an active light-absorbing or light-emitting material to an electrode, which in turn is deposited on a substrate.

One problem associated with the formation of such metal layers is that they must be deposited using techniques that must be carried out at temperatures at which substrate materials, such as polymeric materials, decompose. Current methods of metal deposition on substrates involve processes like physical and chemical vapor deposition, sputtering, evaporation, and molecular beam epitaxy, among other techniques. These processes require high-temperatures, typically above 500° C., which may chemically or electronically degrade the substrate. In addition, such vapor deposition-based techniques are frequently carried out under reduced pressure conditions and do not lend themselves to efficient or large-scale manufacture of such electro-active devices.

Metal films have also been deposited by solution-based methods on a substrate at temperatures of about 400° C. However, even this temperature regime is outside the temperature tolerance for many electronic materials and substrates.

Current methods for forming the metal-containing layers in such electro-active devices must be carried out at temperatures at which substrate materials are not stable. Therefore, what is needed is to provide an electro-active device having a metal-containing layer that is formed at temperatures below those currently employed in deposition. What is also needed is a method of depositing such a metal-containing layer at temperatures below those currently used. What is further needed is a method of depositing such metal-containing layers, wherein the method does not employ vapor deposition to form the metal-containing layer.

### BRIEF SUMMARY OF INVENTION

The present invention meets these and other needs by providing a metal-containing layer that is deposited on a substrate at temperatures below about 200° C. and a method of forming such a metal-containing layer on a substrate. An electro-active device, such as a photovoltaic cell or OLED, having at least such one metal-containing layer, is also provided.

Accordingly, one aspect of the invention is to provide an electro-active device. The electro-active device comprises: a substrate; a first electrode disposed on a surface of the substrate; a second electrode; at least one electro-active layer disposed between the first electrode and the second electrode, wherein the at least one active layer comprises one of a light absorbing layer and a light emitting layer; and a first metal-containing layer disposed between the electro-active layer and one of the first electrode and the second electrode. The first metal-containing layer comprises at least one metal disposed in a plurality of domains, and at least one of the first electrode and second electrode is a transparent electrode, wherein the first metal-containing layer is adjacent to the transparent layer.

A second aspect of the invention is to provide a metal-containing layer for an electro-active device, the metal-containing layer comprising at least one metal disposed in a plurality of domains. The plurality of domains form a layer on a surface of a substrate, and are formed by decomposing a organometallic complex on a substrate and decomposing the organometallic complex at a temperature of less than about 200° C.

A third aspect of the invention is to provide an electro-active device. The electro-active device comprises: a substrate; a first electrode disposed on a surface of the substrate; a second electrode; at least one electro-active layer disposed between the first electrode and the second electrode, wherein the electro-active layer comprises one of a light absorbing layer and a light emitting layer; and a first metal-containing layer disposed between the electro-active layer and one of the first electrode and the second electrode. The first metal-containing layer comprises at least one conductive metal disposed in a plurality of domains. At least one of the first electrode and the second electrode is a transparent electrode, and the first metal-containing layer is transparent to light and adjacent to the transparent layer.

A fourth aspect of the invention is to provide a method of forming a metal-containing layer on a surface of a substrate. The metal-containing layer comprises at least one metal disposed in a plurality of domains, the method comprises: providing at least one organometallic complex of the at least one metal; applying the at least one organometallic complex to the surface; and decomposing the at least one organometallic complex on the surface at a temperature of less than about 200° C. to form the plurality of domains of the at least one metal in elemental form.

These and other aspects, advantages, and salient features of the present invention will become apparent from the following detailed description, the accompanying drawings, and the appended claims.

### BRIEF DESCRIPTION OF DRAWINGS

Referring now to the figures wherein like elements are numbered alike:

FIG. 1 is a schematic representation of a cross-section of an electro-active device of the present invention;

FIG. 2 is a schematic representation of a top view of a metal-containing layer of the present invention disposed upon a surface of an electrode;

FIG. 3 shows the structure of a Karstedt's catalyst;

FIG. 4 shows the chemical reaction for the deposition of elemental platinum using Karstedt's catalyst;

FIG. 5 shows the chemical reaction for the deposition of elemental platinum using dimethyl(1,5-cyclooctadiene) platinum (also referred to herein as “CODPtMe₂” where COD=1,5-cyclooctadiene);

FIG. 6 shows structures of platinum (Pt) organometallic complexes that are used to deposit Pt on electrode/substrate combinations;

FIG. 7 lists experimental conditions that were used to deposit of the platinum (Pt) layers and the contact potential difference values measured for the Pt layers;

FIG. 8 is a scanning electron micrograph (500,000× magnification) of a platinum layer of the present invention deposited on a tin oxide (SnO) electrode; and

FIG. 9 is a spectrum, obtained by energy dispersive spectroscopy (EDS), of the image shown in FIG. 8.

### DETAILED DESCRIPTION

In the following description, like reference characters designate like or corresponding parts throughout the several views shown in the figures. It is also understood that terms such as “top,” “bottom,” “outward,” “inward,” and the like are words of convenience and are not to be construed as limiting terms.

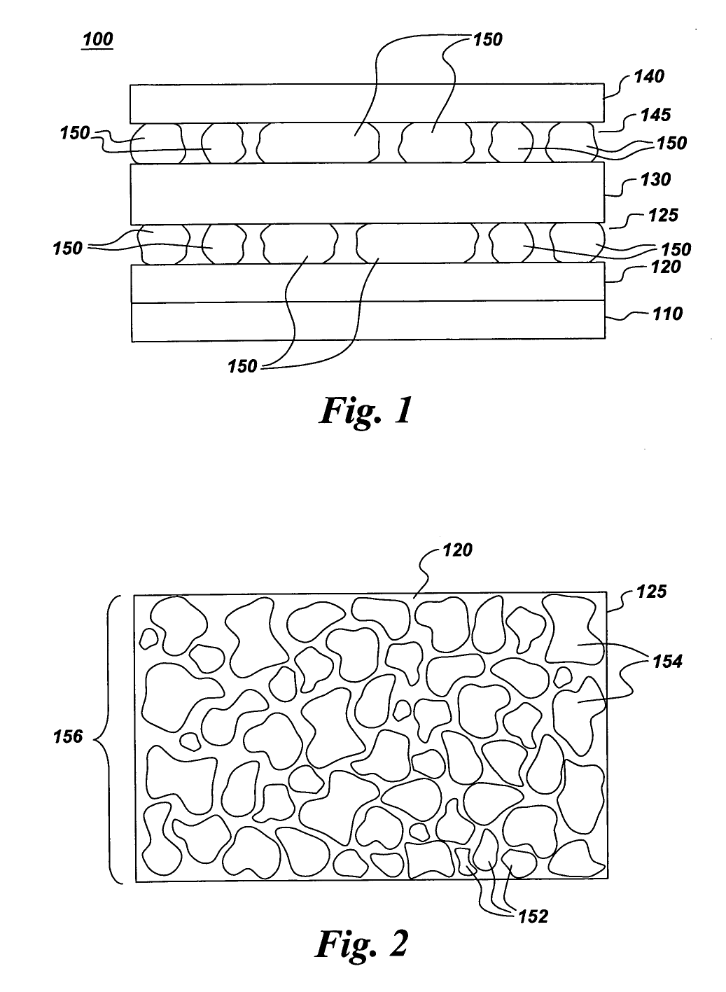

Referring to the drawings in general and to FIG. 1 in particular, it will be understood that the illustrations are for the purpose of describing a particular preferred embodiment of the invention and are not intended to limit the invention thereto. Turning to FIG. 1, a schematic representation of a cross-section of an electro-active device 100 of the present invention is shown. Among the electro-active devices that fall within the scope of the present invention are photovoltaic cells (also referred hereinafter as “PV cells”) and organic light emitting diodes (also referred hereinafter as “OLEDs”). However, it will be appreciated by those skilled in the art that other electro-active devices will fall within the scope of the invention.

Electro-active device 100 comprises a substrate 110, a first electrode 120 disposed on a surface of the substrate, a second electrode 140, and at least one electro-active layer 130 disposed between the first electrode 120 and second electrode 140. Where the electro-active device 100 is a PV cell, the at least one electro-active layer 130 comprises a light absorbing layer. Where the electro-active device 100 is an OLED, the at least one electro-active layer 130 comprises a light emitting layer. The overall structure and materials employed in such PV cells and OLEDs are known in the art. Exemplary electro-active devices of the present invention are described in: U.S. Pat. No. 6,515,314, entitled “Light Emitting Device with Organic Layer Doped with Photoluminescent Materials,” by Anil Raj Duggal et al., issued on Feb. 4, 2003; U.S. patent application Ser. No. 10/425,901, entitled “Light Source with Organic Layer and Photoluminescent Layer,” by Anil Raj Duggal et al., filed Apr. 29, 2003; U.S. patent application Ser. No. 10/316,318, entitled “Dye Sensitized Solar Cells Having Foil Electrodes,” by James Lawrence Spivack et al., filed on Dec. 12, 2002; and U.S. patent application Ser. No. 10/316,317, entitled “Structured Dye Sensitized Solar Cell,” by James Lawrence Spivack et al., filed on Dec. 12, 2002; the contents of which are incorporated herein by reference in their entirety. A first metal-containing layer 125 is disposed between electro-active layer 130 and one of first electrode 120 and second electrode 140. In a PV cell, first metal-containing layer 125 is disposed between second electrode 140 and catalyzes the re-oxidation and recombination of the electrolyte in electro-active layer 130. In an OLED, first metal-containing layer 125 facilitates charge injection by changing the work function of the surface of first electrode 120. Additionally, first metal-containing layer 125 may provide an electrical connection between first electrode 120 and electro-active layer 130. A second metal-containing layer 145 may be optionally disposed between either electro-active layer 130 and one of first electrode 120 and second electrode 140, and may serve the same function as first metal-containing layer 125. While the features of first metal-containing layer 125 are described in detail hereinafter, it is understood that the description applies to second metal-containing layer 145 as well.

In one embodiment, substrate 110 is a glass substrate. In a second embodiment, substrate 110 is a polymeric substrate. The polymeric substrate comprises at least one of a polycarbonate, a polyolefin, a polyester, a polyimide, a polysulfone, an acrylate, and combinations thereof. A non-limiting example of a polycarbonate that may be used as a substrate is bisphenol A (BPA) polycarbonate. Polyolefins that are suitable for use as substrate 110 include, but are not limited to, polyethylene, polypropylene, and combinations thereof. A non-limiting example of a polyester that may be used as substrate 110 is polyethylence terephthalate, and a non-limiting example of a polyimide that may be used as substrate 110 is polyetherimide.

First electrode 120 and second electrode 140 each comprise at least one of a metal oxide, a metal, and combinations thereof. In one embodiment the metal oxide is one of indium oxide, tin oxide, indium tin oxide, zinc oxide, indium zinc oxide, gallium indium tin oxide, zinc indium tin oxide, antimony oxide, and combinations thereof. In another embodiment, the metal oxide further comprises a dopant, such as, but not limited to, gallium, zinc, and combinations thereof. In one embodiment, the metal is one of gold, silver, aluminum, and combinations thereof.

In order to permit light to pass either into (in the case of a PV cell) or out of (in the case of an OLED) electro-active layer 130, at least one of first electrode 120 and second electrode 140 is transparent to light. Such an electrode is also referred to hereinafter as a “transparent electrode.” The first metal-containing layer 125 is disposed between the transparent electrode and electro-active layer 140 and is transparent to light as well. First metal-containing layer 125 is also referred to hereinafter as a “transparent metal-containing layer.” In one embodiment, both the transparent electrode and transparent metal-containing layer are transparent to at least one of ultraviolet, infrared, near-infrared, and visible light. In another embodiment, the transparent electrode and transparent metal-containing layer are transparent to light having a wavelength in a range from about 300 nm to about 10 microns. Preferably, the transparent layer has a transparency of at least about 80%; that is, at least about 80% of the light impinging on a surface of the transparent conductive is transmitted through the transparent metal-containing layer.

First metal-containing layer 125 comprises at least one metal. In one embodiment, the at least one metal comprises at least one transition metal. In one embodiment, the at least one transition metal is one of platinum, palladium, gold, silver, ruthenium, osmium, iridium, rhodium, copper, nickel, aluminum, and combinations thereof. Preferably, the at least one transition metal is one of platinum, gold, and combinations thereof.

In first metal-containing layer 125, the metal is disposed in a plurality of domains (or regions) 150. It is understood that second metal-containing layer 145 may have the same structure as that described herein for first metal-containing layer 125. In one embodiment, the plurality of domains 150 forms a metal-containing layer that is discontinuous. FIG. 2 is a schematic representation of a top view of first metal-containing layer 125 disposed upon a surface of first electrode 120. The plurality of domains 150 is discontinuous, and includes both individual domains 152 that are freestanding and networked domains 154, where a plurality of individual domains overlap each other. The first metal-containing layer 125 formed from the plurality of domains 150 is a discontinuous layer 156, and does not totally cover first electrode 120, as seen in FIG. 2. In a PV cell, first metal-containing layer 125 is disposed between second electrode 140 and catalyzes the re-oxidation and recombination of the electrolyte in electro-active layer 130. In an OLED, first metal-containing layer 125 facilitates charge injection by changing the work function of the surface of first electrode 120. First metal-containing layer 125 amy also serve as a conductive layer. To provide an adequate catalytic (in a PV cell) or charge-injection (in an OLED) capability, discontinuous layer 156, in one embodiment, covers at least one percent of the surface of at least one of first metal-containing layer 125 and second metal-containing layer 135.

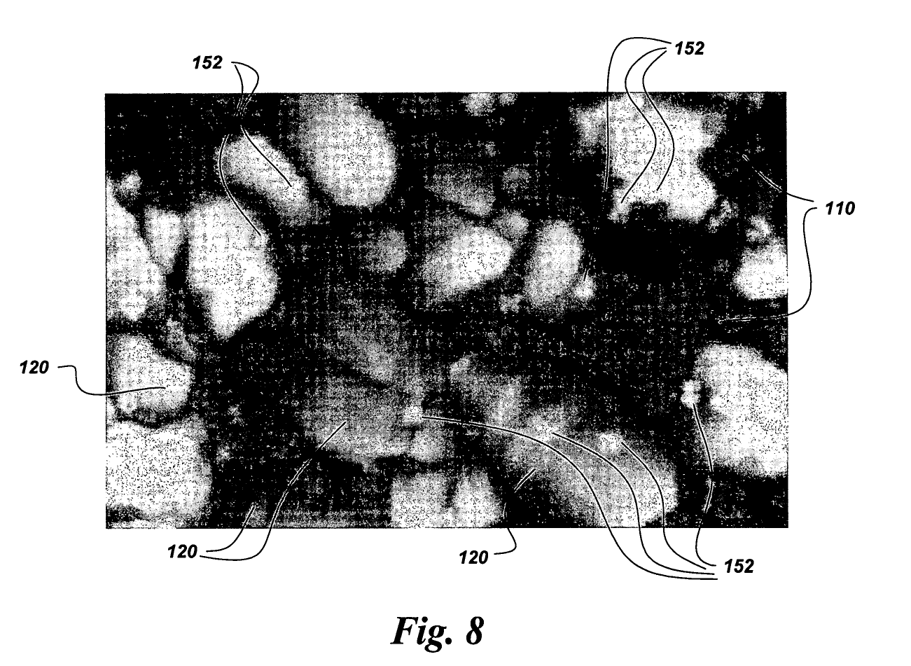

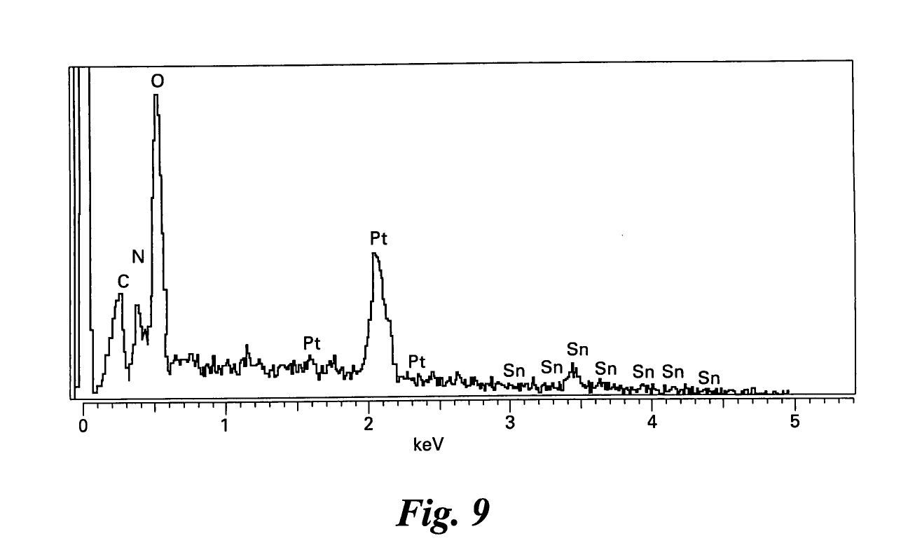

FIG. 8 is a scanning electron micrograph image (500,000× magnification) of metal-containing layer 125, comprising elemental platinum, of the present invention deposited on a tin oxide (SnO) electrode, showing individual domains 152 of platinum metal forming a discontinuous layer on SnO grains that form electrode 120. Portions of substrate 110 are also visible. FIG. 9 shows results of energy dispersive spectroscopic analysis of the region shown in FIG. 8, and confirms the presence of Pt domains on SnO.

In one embodiment, first metal-containing layer 125 comprises less than a monolayer of the at least one metal on one of first electrode 120 and second electrode 140. In another embodiment, first metal-containing layer 125 comprises a plurality of domains 150 that form a substantially continuous metal-containing layer. The substantially continuous metal-containing layer, in one embodiment, has a thickness in a range from about 0.5 nm to about 100 nm.

In order for first metal-containing layer 125 to be transparent to a predetermined wavelength of radiation, the plurality of domains 150 within first metal-containing layer 125 has a mean diameter that is less than the predetermined wavelength of radiation. Thus, in one embodiment, first metal-containing layer 125 will be transparent to ultraviolet radiation if the mean diameter of the plurality of domains comprising first metal-containing layer 125 is less than the wavelength of ultraviolet radiation. In another embodiment, first metal-containing layer 125 will be transparent to visible light if the mean diameter of the plurality of domains comprising first metal-containing layer 125 is less than the wavelength of visible light. In still another embodiment, first metal-containing layer 125 will be transparent to near infrared or infrared radiation if the mean diameter of the plurality of domains comprising first metal-containing layer 125 is less than the wavelength of near infrared or infrared radiation, respectively.

One effect of first metal-containing layer 125 of the present invention is to change the work function of the surface of the adjacent electrode. In one embodiment, first metal-containing layer 125 produces a change of at least 0.1 eV in the work function of the surface of the adjacent electrode.

Another aspect of the present invention is to provide a method of forming a metal-containing layer comprising at least one metal, as described herein, on a surface of a substrate, such as, but not limited to, an electrode of an opto-electronic device. The at least one metal is disposed on a surface of the substrate in a plurality of domains. The method comprises the steps of providing at least one organometallic complex of the at least one metal, applying the at least one organometallic complex to the surface of the substrate, and decomposing the at least one organometallic complex on the surface at a temperature of less than about 200° C. to form the plurality of domains of the at least one metal.

The at least one organometallic complex may be selected from those organometallic compounds that are typically used in the art as precursors in metal organic chemical vapor deposition (MOCVD). In one embodiment, the at least one organometallic complex comprises at least one organometallic complex of a transition metal. In a preferred embodiment, the transition metal is one of platinum, palladium, gold, silver, ruthenium, osmium, iridium, rhodium, copper, nickel, aluminum, and combinations thereof. In a more preferred embodiment, the transition metal is one of platinum, gold, and combinations thereof. Non-limiting examples of organometallic complexes that may be used include (bis(divinyltetramethyldisiloxy)platinum1,5-cyclooctadiene (also referred to hereinafter as “Karstedt's catalyst”), dimethyl(1,5-cyclooctadiene) platinum (also referred to herein as “CODPtMe₂”), iodotrimethylplatinum, platinum acetylacetonate, platinum hexafluoroacetylacetonate, (trimethyl)methylcyclopentadienyl platinum (also referred to herein as “MeCpPtMe₃”), (trimethyl)cyclopentadienyl platinum, silveracetylacetonate, dimethyl(acetylacetonate)gold, bis(1,5-cyclooctadiene)nickel, bis(cyclopentadienyl)nickel, palladium acetylacetonate, tris(dibenzylideneacetone)dipalladium, and the like.

A solution of the at least one organometallic complex is then formed by dissolving the at least one organometallic compound in a solvent. In one embodiment, the solvent is an organic solvent, such as, but not limited to, xylene, toluene, benzene, tetrahydrofuran, methylene dichloride, an alkane, combinations thereof, and the like. Alternatively, the solution is substantially free of aromatic solvent and comprises the at least one organometallic complex and a mixture of silicon-vinyl-containing siloxane oligomers.

The solution comprises at least about 0.1 weight percent of the at least one metal. In one embodiment, the solution comprises from about 0.1 weight percent to about 15 weight percent of the at least one metal. Alternatively, the solution may be a saturated solution of the at least one metal.

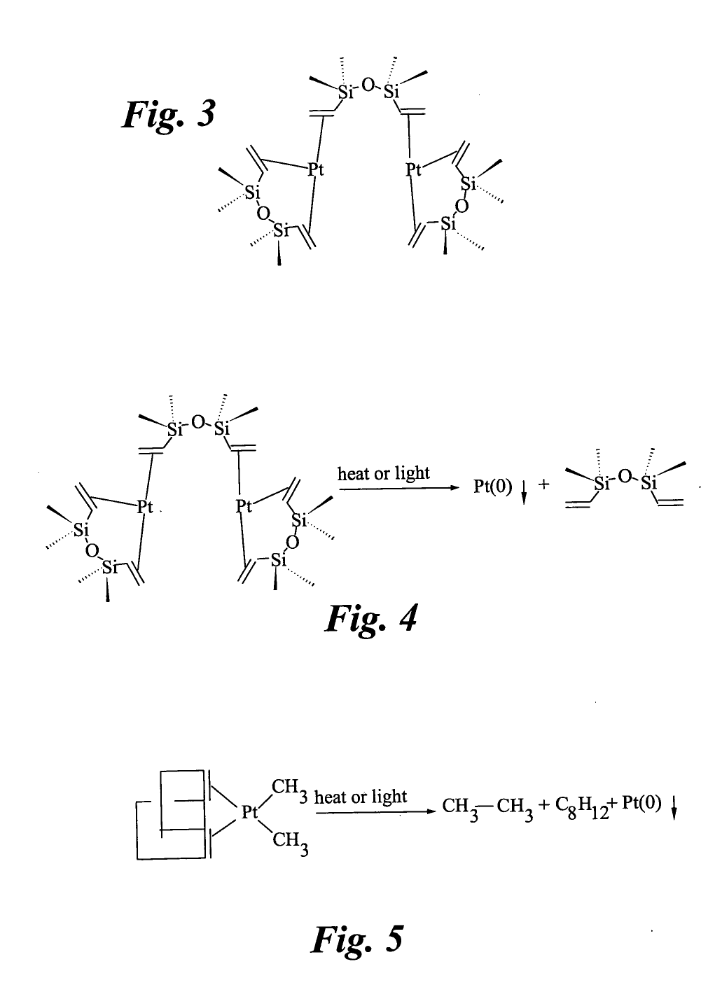

In one particular embodiment, a solution comprises a solvent and a Karstedt's catalyst or any low valent solutions of the at least one metal containing vinyl-siloxane ligands, described in “Mechanism of Formation of Platinum(0) Complexes Containing Silicon-Vinyl Ligand,” by L. N. Lewis, R. E. Colborn, H Grade, G. L. Bryant, C. A. Sumpter, R. A. Scott, Organometallics, 14 (1995) 2202, the contents of which are incorporated herein by reference in their entirety. The structure of a Karstedt's catalyst is shown in FIG. 3.

For example, a platinum solution with from about 0.1 to about 50 mole excess (based on Pt) of any Si—H containing monomer or polymer such as (EtO)₃SiH, Et₃SiH or Si—H on chain polymethylsiloxane polymers may be prepared, as described in U.S. Pat. No. 4,681,963, entitled “Hydrosilylation Catalyst, Method for Making and Use,” by L. N. Lewis, issued on Jul. 21, 1987; and U.S. Pat. No. 4,705,765, entitled “Hydrosilylation Catalyst, Method for Making and Use,” by L. N. Lewis, issued on Nov. 10, 1987, the contents of which are incorporated herein by reference in their entirety.

The solution comprising the at least one organometallic complex is then applied to the surface of the substrate. Where the metal-containing layer is to be part of an opto-electronic device, such as that shown in FIG. 1, the substrate comprises an electrode. The electrode may be at least one of first electrode 120 and second electrode 140, as shown in FIG. 1. In this instance, the electrode itself may be disposed on another substrate. In FIG. 1, for example, first electrode 120 is disposed on substrate 110. The solution is applied to the substrate using solution application techniques that are known in the art. Such techniques include, but are not limited to, spin coating, printing, spray coating, dip coating, roller coating, blade coating, combinations thereof, and the like.

Once applied to the surface of the substrate, the at least one organometallic complex is decomposed at a temperature of less than about 200° C. to form a free-standing metal-containing layer comprising the at least one metal in elemental (also known as a “zero valent metal”) form. Decomposition may take place in either a vacuum or in a stream of gas, such as, but not limited to, an inert gas. In most instances, the solvent is highly volatile and readily vaporizes to leave behind a film of the at least one organometallic complex. In one embodiment, decomposition is achieved by heating the solution applied to the surface of the substrate using heating means that are known in the art such as, but not limited to, furnaces, heat lamps, and forced hot-air heating. The temperature to which the solution or organometallic complex is heated depends upon the thermal stability of the organometallic complex. In one embodiment, the temperature is in a range from about 20° C. to about 200° C. In a second embodiment, the temperature is in a range from about 100° C. to about 200° C. In a third embodiment, the temperature is in a range from about 120° C. to about 180° C.

In another embodiment, the at least one organometallic complex is decomposed by irradiating the film or solution on the surface of the substrate. The film or solution may be irradiated by ‘actinic’ radiation: radiation that is sufficiently energetic to break the bonds within the at least one organometallic complex and produce the zero valent metal. In one embodiment, decomposition occurs by irradiating the at least one organometallic complex with ultraviolet radiation. In another embodiment, the organometallic complex is irradiated with an electron beam to decompose the organometallic complex.

By decomposing the organometallic complex at less than about 200° C., damage to substrates, such as polymeric substrates and the like, that have low melting or glass transition temperatures is avoided. Moreover, the solution-based process lends itself to high-throughput manufacturing techniques, such as roll-to-roll processing.

The following example is included to illustrate the various features and advantages of the present invention, and is not intended to limit the invention in any way.

### EXAMPLE 1

The initial experiments for low temperature deposition of elemental platinum (Pt(0)) used Karstedt's catalyst solutions. The deposition of elemental platinum using Karstedt's catalyst proceeds according to the reaction shown in FIG. 4. The decomposition temperature was greater than 100° C., and in most instances was about 150° C. Xylene solutions of Karstedt's catalyst were spin coated onto a substrate and then heated to about 150° C. It was later found that better adhesion was obtained when HMDZ (hexamethyldisilazane) was used as a diluent. Cyclic voltammetry (CV) analyses of the Karstedt's catalyst-derived films were consistent with the presence of elemental Pt(0) on the surface of the substrate.

In some instances, films made using Karstedt's catalyst, produced films that were clear but brown in color. Other Pt precursors having volatile ligands were used to obtain ‘clean’—i.e., substantially residue-free—decomposition to Pt. The precursor dimethyl(1,5-cyclooctadiene) platinum (also referred to herein as “CODPtMe₂” where COD=1,5-cyclooctadiene), for example, decomposes via reductive elimination of ethane and loss of the COD ligand. In addition, CODPtMe₂, which is soluble in octane, a solvent compatible with most plastics that are candidate substrate materials. The deposition of elemental platinum using CODPtMe₂ proceeds according to the reaction shown in FIG. 5. The films obtained using the CODPtMe₂ precursor were colorless. Cyclic voltammetry analyses of Pt films derived from CODPtMe₂ were nearly identical in appearance to those obtained for Pt films that were formed using high temperature deposition processes.

### EXAMPLE 2

The possible performance of a Pt-containing layer of the present invention in an electro-active device such as a photovoltaic (PV) cell may be correlated with Kelvin probe measurements. The Kelvin probe gives a CPD (contact potential difference) value, which is directly related to the work function of a sample. Thus, a change in CPD value between samples is directly related to a corresponding change in work function; if a standard is known, then the absolute work function of an unknown sample can be determined.

Platinum-containing layers of the present invention were deposited on two combinations of electrode materials and substrates: tin oxide (SnO) deposited on glass; and indium tin oxide (ITO) deposited on Lexan® (polycarbonate). The CPD values obtained for SnO deposited on glass and ITO on Lexan® were −0.385 V and −0.503 V, respectively.

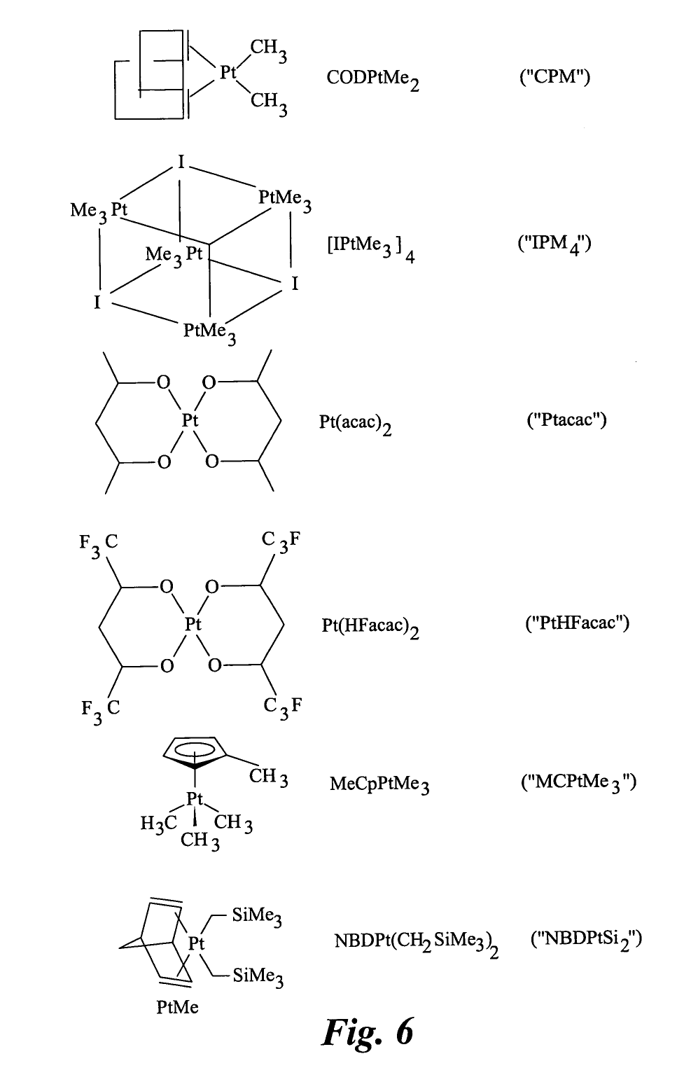

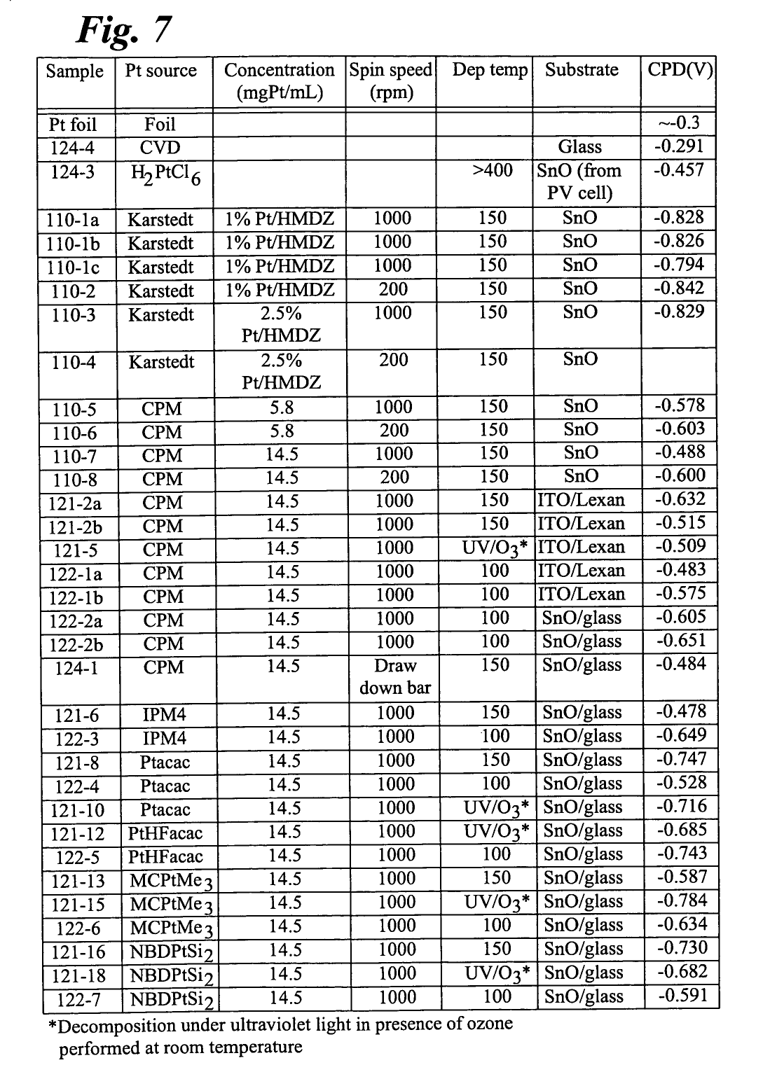

The structures of the Pt organometallic complexes that were used to deposit Pt on the electrode/substrate combinations are listed in FIG. 6. Experimental conditions that were used to deposit of the Pt-containing layers, including the Pt organometallic precursor, deposition conditions, decomposition temperatures, and substrates, are listed in FIG. 7. In some instances, the organometallic complex was decomposed by irradiating the organometallic complex with ultraviolet (UV) light in the presence of ozone at room temperature. Contact potential difference values obtained for the samples, as well as CPD values that were obtained for Pt foil, Pt deposited by chemical vapor deposition (CVD), and Pt deposited at high temperature (400° C.), are also listed in FIG. 7. The platinum coating deposited in sample 110-4 was too thick to obtain a CPD value.

The CPD value of high temperature-derived Pt on SnO (taken from an actual photovoltaic cell) had a 0.15 V more negative CPD value than either Pt foil or Pt deposited on glass by CVD. The CPD values measured for Pt-containing layers derived from the Karstedt-catalyst are about 0.4 V more negative than the platinum layer deposited at high temperature, whereas the CPM-derived Pt exhibited CPD values that were equivalent to that of the platinum layer deposited at high temperature.

All of the organometallic complexes decomposed to either photochemically or thermally to yield elemental platinum (Pt(0)). CPD values of less than about −0.6 V will lead to good PV cell performance. In most instances, acceptable performance can be obtained by decomposing the organometallic precursors to provide a platinum layer at 150° C. instead of 100° C. However, some precursors, such as Ptacac and CPM, when decomposed at 100° C., provide a platinum layer having adequate performance. In addition, CPM, when decomposed in the UV/O₃ chamber at room temperature, provided a platinum layer having adequate performance.

While typical embodiments have been set forth for the purpose of illustration, the foregoing description should not be deemed to be a limitation on the scope of the invention. Accordingly, various modifications, adaptations, and alternatives may occur to one skilled in the art without departing from the spirit and scope of the present invention.

1. An electro-active device, said electro-active device comprising,
a) a substrate;
b) a first electrode disposed on a surface of said substrate;
c) a second electrode;
d) at least one electro-active layer disposed between said first electrode and said second electrode, wherein said at least one active layer comprises one of a light absorbing layer and a light emitting layer;
e) a first metal-containing layer disposed between said electro-active layer and one of said first electrode and said second electrode; wherein said first metal-containing layer comprises at least one metal disposed in a plurality of domains, and wherein at least one of said first electrode and said second electrode is a transparent electrode.

2. The electro-active device according to claim 1, wherein said first metal-containing layer is disposed between said active layer and said transparent electrode and is transparent to light.

3. The electro-active device according to claim 1, wherein said first metal-containing layer is transparent to light having a wavelength in a range from about 300 nm to about 10 microns.

4. The electro-active device according to claim 1, wherein said first metal-containing layer and said transparent electrode are transparent to at least one of ultraviolet, infrared, near infrared, and visible light.

5. The electro-active device according to claim 1, wherein said first metal-containing layer has a transparency to light of at least 80%.

6. The electro-active device according to claim 1, wherein said at least one metal comprises at least one transition metal.

7. The electro-active device according to claim 6, wherein said at least one transition metal is one of platinum, palladium, gold, silver, ruthenium, osmium, iridium, rhodium, copper, nickel, aluminum, and combinations thereof.

8. The electro-active device according to claim 7, wherein said at least one transition metal is one of platinum, gold, and combinations thereof.

9. The electro-active device according to claim 1, wherein each of said plurality of domains has a mean diameter of less than the wavelength of ultraviolet light.

10. The electro-active device according to claim 1, wherein each of said plurality of domains has a mean diameter of less than the wavelength of visible light.

11. The electro-active device according to claim 1, wherein each of said plurality of domains has a mean diameter of less than the wavelength of near infrared radiation.

12. The electro-active device according to claim 1, wherein said plurality of domains has a mean diameter of less than the wavelength of infrared radiation.

13. The electro-active device according to claim 1, wherein said plurality of domains forms a discontinuous layer on a surface of at least one of said first electrode and said second electrode.

14. The electro-active device according to claim 13, wherein said discontinuous layer covers at least one percent of said surface.

15. The electro-active device according to claim 1, wherein said plurality of domains forms a substantially continuous layer on a surface of at least one of said first electrode and said second electrode.

16. The electro-active device according to claim 15, wherein said substantially continuous layer has a thickness in a range from about 0.5 nm to about 100 nm.

17. The electro-active device according to claim 1, wherein at least one of said first metal-containing layer and second metal-containing layer comprises less than a monolayer of said at least one metal on a surface of at least one of said first electrode and said second electrode.

18. The electro-active device according to claim 1, wherein said first metal-containing layer effects a change of at least 0.1 eV in a work function of a surface of at least one of said first electrode and said second electrode.

19. The electro-active device according to claim 1, wherein said electro-active device is a photovoltaic cell.

20. The electro-active device according to claim 1, wherein said electro-active device is an organic light emitting diode.

21. The electro-active device according to claim 1, wherein said substrate is a glass substrate.

22. The electro-active device according to claim 1, wherein said substrate is a polymeric substrate.

23. The electro-active device according to claim 22, wherein said polymeric substrate comprises at least one of a polycarbonate, a polyolefin, a polyester, a polyimide, a polysulfone, an acrylate, and combinations thereof.

24. The electro-active device according to claim 1, wherein said transparent electrode comprises at least one of a metal oxide, a metal, and combinations thereof.

25. The electro-active device according to claim 24, wherein said metal oxide is one of indium oxide, tin oxide, indium tin oxide, zinc oxide, indium zinc oxide, gallium indium tin oxide, zinc indium tin oxide, antimony oxide, and combinations thereof.

26. The electro-active device according to claim 25, wherein said metal oxide further comprises at least one dopant, wherein said at least one dopant is gallium, zinc, and combinations thereof.

27. The electro-active device according to claim 24, wherein said metal is one of gold, silver, aluminum, and combinations thereof.

28. The electro-active device according to claim 1, further comprising a second metal-containing layer disposed between said least one active layer and one of said first electrode and said second electrode.

29. A metal-containing layer for an electro-active device, said metal-containing layer comprising at least one metal disposed in a plurality of domains, wherein said plurality of domains form a layer on a surface of a substrate, and wherein said plurality of domains are formed by decomposing a organometallic complex on a substrate and decomposing said organometallic complex at a temperature of less than about 200° C.

30. The metal-containing layer according to 29, wherein said metal-containing layer is transparent to light.

31. The metal-containing layer according to 29, wherein said metal-containing layer is transparent to light having a wavelength in a range from about 300 nm to about 10 microns.

32. The metal-containing layer according to 29, wherein said metal-containing layer is transparent to at least one of infrared, near infrared, and visible light.

33. The metal-containing layer according to claim 29, wherein said metal-containing layer has a transparency to light of at least 80%.

34. The metal-containing layer according to claim 29, wherein said at least one metal comprises at least one transition metal.

35. The metal-containing layer according to claim 34, wherein said at least one transition metal is one of platinum, palladium, gold, silver, ruthenium, osmium, iridium, rhodium, copper, nickel, aluminum, and combinations thereof.

36. The metal-containing layer according to claim 35, wherein said at least one transition metal is at least one of platinum, gold, and combinations thereof.

37. The metal-containing layer according to claim 29, wherein each of said plurality of domains has a mean diameter of less than the wavelength of ultraviolet light.

38. The metal-containing layer device according to claim 29, wherein said plurality of domains has a mean diameter of less than the wavelength of visible light.

39. The metal-containing layer according to claim 29, wherein said plurality of domains has a mean diameter of less than the wavelength of near infrared radiation.

40. The metal-containing layer according to claim 29, wherein said plurality of domains has a mean diameter of less than the wavelength of infrared radiation.

41. The metal-containing layer according to claim 29, wherein each of said plurality of domains has a mean diameter of less than about 200 nm.

42. The metal-containing layer according to claim 29, wherein said metal-containing layer comprises less than a monolayer of said at least one conductive metal disposed on said surface.

43. The metal-containing layer according to claim 29, wherein said plurality of domains forms a discontinuous layer on said surface.

44. The metal-containing layer according to claim 43, wherein said discontinuous layer covers at least one percent of said surface.

45. The metal-containing layer according to claim 29, wherein said plurality of domains forms a substantially continuous layer on said surface.

46. The metal-containing layer according to claim 45, wherein said substantially continuous layer has a thickness in a range from about 0.5 nm to about 100 nm.

47. The metal-containing layer according to claim 29, wherein said metal-containing layer comprises less than a monolayer of said at least one metal on said surface.

48. The metal-containing layer according to claim 29, wherein said metal-containing layer effects a change of at least 0.1 eV in a work function of said surface.

49. The metal-containing layer according to claim 29, wherein said organometallic complex is decomposed by heating said organometallic complex to a temperature of less than about 200° C.

50. The metal-containing layer according to claim 29, wherein said organometallic complex is decomposed by irradiating said organometallic complex at a temperature of less than about 200° C.

51. An electro-active device, said electro-active device comprising,
a) a substrate;
b) a first electrode disposed on a surface of said substrate;
c) a second electrode;
d) at least one electro-active layer disposed between said first electrode and said second electrode, wherein said at least one active layer comprises one of a light absorbing layer and a light emitting layer;
e) a first metal-containing layer disposed between said electro-active layer and one of said first electrode and said second electrode, wherein said first metal-containing layer comprises at least one metal disposed in a plurality of domains, wherein at least one of said first electrode and said second electrode is a transparent electrode, and wherein said first metal-containing layer is disposed between said active layer and said transparent electrode and is transparent to light.

52. The electro-active device according to claim 51, wherein said first metal-containing layer has a transparency to visible light of at least 80%.

53. The electro-active device according to claim 51, wherein said first metal-containing layer is transparent to light having a wavelength in a range from about 300 nm to about 10 microns.

54. The electro-active device according to claim 51, wherein said first metal-containing layer and said transparent electrode are transparent to at least one of infrared, near infrared, and visible light.

55. The electro-active device according to claim 51, wherein said first metal-containing layer has a transparency to light of at least 80%.

56. The electro-active device according to claim 51, wherein said at least one metal comprises at least one transition metal.

57. The electro-active device according to claim 56, wherein said at least one transition metal is one of platinum, palladium, gold, silver, ruthenium, osmium, iridium, rhodium, copper, nickel, aluminum, and combinations thereof.

58. The electro-active device according to claim 57, wherein said at least one transition metal is at least one of platinum, gold, and combinations thereof.

59. The electro-active device according to claim 51, wherein said plurality of domains has a mean diameter of less than the wavelength of ultraviolet light.

60. The electro-active device according to claim 51, wherein said plurality of domains has a mean diameter of less than the wavelength of visible light.

61. The electro-active device according to claim 51, wherein said plurality of domains has a mean diameter of less than the wavelength of near infrared radiation.

62. The electro-active device according to claim 51, wherein said plurality of domains has a mean diameter of less than the wavelength of infrared radiation.

63. The electro-active device according to claim 51, wherein said plurality of domains form a discontinuous layer on a surface of at least one of said first electrode and said second electrode.

64. The electro-active device according to claim 51, wherein said plurality of domains forms a discontinuous layer on a surface of at least one of said first electrode and said second electrode.

65. The electro-active device according to claim 64, wherein said discontinuous layer covers at least one percent of said surface.

66. The electro-active device according to claim 51, wherein said plurality of domains forms a substantially continuous layer on a surface of at least one of said first electrode and said second electrode.

67. The electro-active device according to claim 66, wherein said substantially continuous layer has a thickness in a range from about 0.5 nm to about 100 nm.

68. The electro-active device according to claim 51, wherein said first metal-containing layer comprises less than a monolayer of said at least one metal on a surface of at least one of said first electrode and said second electrode.

69. The electro-active device according to claim 51, wherein at least one of said first metal-containing layer and said second metal-containing layer effects a change of at least 0.1 eV in a work function of a surface of at least one of said first electrode and said second electrode.

70. The electro-active device according to claim 51, wherein said electro-active device is a photovoltaic cell.

71. The electro-active device according to claim 51, wherein said electro-active device is an organic light emitting diode.

72. The electro-active device according to claim 51, wherein said substrate is a glass substrate.

73. The electro-active device according to claim 51, wherein said substrate is a polymeric substrate.

74. The electro-active device according to claim 73, wherein said polymeric substrate comprises at least one of a polycarbonate, a polyolefin, a polyester, a polyimide, a polysulfone, an acrylate, and combinations thereof.

75. The electro-active device according to claim 51, wherein said transparent electrode comprises at least one of a metal oxide, a metal, and combinations thereof.

76. The electro-active device according to claim 75, wherein said metal oxide is one of indium oxide, tin oxide, indium tin oxide, zinc oxide, indium zinc oxide, gallium indium tin oxide, zinc indium tin oxide, antimony oxide, and combinations thereof.

77. The electro-active device according to claim 76, wherein said metal oxide further comprises wherein said metal oxide further comprises at least one dopant, wherein said at least one dopant is one of gallium, zinc, and combinations thereof.

78. The electro-active device according to claim 75, wherein said metal is one of gold, silver, aluminum, and combinations thereof.

79. The electro-active device according to claim 51, wherein plurality of domains are formed by decomposing a organometallic complex on a substrate and decomposing said organometallic complex at a temperature of less than about 200° C.

80. The electro-active device according to claim 51, further comprising a second metal-containing layer disposed between said least one active layer and one of said first electrode and said second electrode.

81. A method of forming a metal-containing layer on a surface of a substrate, wherein the metal-containing layer comprises at least one metal disposed in a plurality of domains, the method comprising the steps of:
a) providing at least one organometallic complex of the at least one metal;
b) applying the at least one organometallic complex to the surface; and
c) decomposing the at least one organometallic complex on the surface at a temperature of less than about 200° C. to form the plurality of domains of the at least one metal in elemental form.

82. The method according to claim 82, wherein the step of providing at least one organometallic complex of the at least one metal comprises the steps of:
a) providing the at least one organometallic complex;
b) providing a solvent;
d) forming a solution of the at least one organometallic complex in the solvent; and
e) applying the solution to the surface.

83. The method according to claim 82, wherein the solvent is an organic solvent.

84. The method according to claim 83, wherein the solvent comprises at least one of xylene, toluene, benzene, tetrahydrofuran, methylene dichloride, an alkane, and combinations thereof.

85. The method according to claim 82, wherein the solvent is substantially free of aromatic compounds.

86. The method according to claim 85, wherein the solvent comprises at least one silicon vinyl containing siloxane oligomer.

87. The method according to claim 82, wherein the solution is a solution comprising the at least one metal in a low valence state and vinyl siloxane ligands.

88. The method according to claim 87, wherein the solution comprises (bis(divinyltetramethyldisiloxy)platinum1,5-cyclooctadiene.

89. The method according to claim 82, wherein the solution comprises at least about 0.1 weight percent of the at least one metal.

90. The method according to claim 89, wherein the solution comprises from about 0.1 weight percent to about 15 weight percent of the at least one metal.

91. The method according to claim 89, wherein the solution is a saturated solution of the at least one metal.

92. The method according to claim 81, wherein the at least one metal comprises a transition metal.

93. The method according to claim 92, wherein the transition metal is one of platinum, palladium, gold, silver, ruthenium, osmium, iridium, rhodium, copper, nickel, aluminum, and combinations thereof.

94. The method according to claim 93, wherein the transition metal is platinum.

95. The method according to claim 81, wherein the step of applying the solution to the surface comprises at least one of spin coating the solution onto the surface of the substrate, printing the solution onto the substrate, bar coating the solution onto the substrate, spray coating the solution onto the substrate, dip coating the solution onto the substrate, roller coating the solution onto the substrate, and blade coating the solution onto the substrate.

96. The method according to claim 81, wherein the step of decomposing the at least one organometallic complex on the surface at a temperature below about 200° C. comprises heating the at least one organometallic to a temperature in a range from about 20° C. to about 200° C.

97. The method according to claim 96, wherein the step of decomposing the at least one organometallic complex on the surface at a temperature in a range from about 20° C. to about 200° C. comprises heating the at least one organometallic compound to a temperature in a range from about 100° C. to about 200° C.

98. The method according to claim 97, wherein the step of decomposing the at least one organometallic complex on the surface at a temperature in a range from about 20° C. to about 200° C. comprises heating the at least one organometallic to a temperature in a range from about 120° C. to about 180° C.

99. The method according to claim 81, wherein the step of decomposing the at least one organometallic complex on the surface at a temperature below about 200° C. comprises irradiating the at least one organometallic complex on the surface.

100. The method according to claim 99, wherein the step of irradiating the at least one organometallic complex on the surface comprises irradiating the at least one organometallic complex on the surface with ultraviolet radiation.

101. The method according to claim 81, wherein the step of applying the at least one organometallic complex to the surface comprises applying an amount of the at least one metal sufficient to form a coating that is electrically conductive and transparent to visible light.

102. The method according to claim 81, wherein the substrate comprises an electrode of an electro-active device.

103. The method according to claim 102, wherein the electro-active device is one of a photovoltaic cell and an organic light emitting diode.

104. The method according to claim 81, wherein the at least one organometallic complex comprises at least one transition metal.

105. The method according to claim 104, wherein the at least one transition metal is one of platinum, palladium, gold, silver, ruthenium, osmium, iridium, rhodium, copper, nickel, aluminum, and combinations thereof.

106. The method according to claim 105, wherein the at least one transition metal is one of platinum, gold, and combinations thereof.

107. The method according to claim 104, wherein the at least one transition metal is in the zero (0) oxidation state.

108. The method according to claim 81, wherein the at least one organometallic complex is one of dimethyl(1,5-cyclooctadiene) platinum, (trimethyl)methylcyclopentadienyl platinum, and combinations thereof.

109. The method according to claim 81, wherein the plurality of domains disposed within the metal-containing layer is discontinuous.

110. The method according to claim 81, wherein the plurality of domains disposed form a continuous metal-containing layer.
